(19) United States
(12) Patent Application Publication
(10) Pub. No.: US 2026/0237885 A1
(43) Pub. Date: Aug. 13, 2026

(54) ANTENNA IN PACKAGE STRUCTURE AND DESIGN METHOD

(71) Applicant: METAWAVE CORPORATION, Carlsbad, CA (US)

(72) Inventors: Kevin GU, Carlsbad, CA (US); Hadi Saeidi MANESH, Carlsbad, CA (US); Neda BATHAEI, Carlsbad, CA (US); Ricky Donald HECKLER, Carlsbad, CA (US); Raymond Anthony HAYNES, Carlsbad, CA (US); Andrew John BONTHRON, Carlsbad, CA (US)

(21) Appl. No.: 19/147,708

(22) PCT Filed: Jan. 3, 2024
(86) PCT No.: PCT/US2024/010204

§ 371 Date: Jul. 13, 2025

Related U.S. Application Data
(60) Provisional application No. 63/438,961, filed on Jan. 13, 2023.

(51) Int. Cl. H01Q 1/22; H01Q 19/00; H10W 70/65

(52) U.S. Cl. CPC H01Q 1/2283; H01Q 19/005; H10W 70/65

(57) ABSTRACT

In accordance with various embodiments, a multi-layer electromagnetic antenna in package (AiP) device is provided. The device has a plurality of radiating elements configured in a symmetric pattern. Each of the radiating elements having a transmission line through the multi-layer device. Each of the transmission lines having a same electrical length to maintain a consistent phase of transmission signals. The device has a resonant cavity formed within the layers.

### CROSS-REFERENCE TO RELATED APPLICATION

This application claims priority to and the benefit of International Patent Application No. PCT/US2024/010204 filed Jan. 3, 2024, which claims priority to and the benefit of U.S. Provisional Patent Application No. 63/438,961, filed on Jan. 13, 2023, the contents of which are hereby incorporated by reference in their entirety.

### BACKGROUND

In multi-layer semiconductor devices transmission lines are routed through and between layers forming complex mappings. The specific mapping may result in unwanted interactions between transmission lines and layers. The length of the transmission lines in complex configures incurs different electrical lengths, complicating design. As these mappings reduce in scale, these effects impact operation of a device. Therefore, there is a need for an improved method and/or apparatus configuration that is capable of resolving the current challenges in fabrication of devices with reduced dimensions.

### BRIEF DESCRIPTION OF THE DRAWINGS

The present application may be more fully appreciated in connection with the following detailed description taken in conjunction with the accompanying drawings, which are not drawn to scale, in which like reference characters refer to like parts throughout, and in which:

FIG. 1 illustrates an example configuration of an integrated circuity having a plurality of elements in a top view and a perspective view, according to various examples;

FIG. 2 illustrates a multi-layer device for an antenna in package, according to various examples;

FIGS. 3A-3D illustrate layers of an example multi-layer device, in accordance with various examples;

FIGS. 4A and 4B illustrate layers of an example multi-layer device, in accordance with various examples;

FIG. 5 illustrates a top view of an example multi-layer device, in accordance with various examples;

FIGS. 6A-6D illustrate a top view of multiple transitions in a layer of a multi-layer device, in accordance with various examples;

FIGS. 7A-7C illustrate a top view of multiple layers of configuration of transmission path transitions through a multi-layer device, in accordance with various examples;

FIGS. 8A-8D illustrate a top view of multiple layers of configuration of transmission path transitions through a multi-layer device, in accordance with various examples; and

FIG. 9 illustrates a process of designing antenna, transmission lines and transitions in a multi-layer IC device, in accordance with various examples.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, the subject technology is not limited to the specific details set forth herein and may be practiced using one or more implementations. In one or more instances, structures and components are shown in block diagram form in order to avoid obscuring the concepts of the subject technology. In other instances, well-known methods and structures may not be described in detail to avoid unnecessarily obscuring the description of the examples. Also, the examples may be used in combination with each other.

The present disclosure provides apparatuses and methods to achieve desired operation of an integrated circuit (IC), and specifically enables millimeter wave operations, incorporating antenna, transmission line and transition structures, shapes and formations within one or more layers of the IC. The IC may support any of a variety of devices and is particularly for an Antenna in Package (AiP) based device, in accordance with various embodiments disclosed in this application.

The present disclosure provides structures for an AiP device for technologies designed at millimeter wave frequencies. These structures enable optimum operation of ultra-wideband package designs including radar systems, wireless communication systems, such as for 5G and beyond. These structures achieve the desired performance by implementation of symmetric designs and improve the operational bandwidth of the system. In determining the layers to implement these structures, the goal is to design the transitions between the layers so as to maintain consistent electrical length and uniform electrical current distribution throughout the layers. This is achieved by positioning antenna radiating elements in a symmetric pattern, designing the transmission lines to have an equal electrical length, and transitions through various layers provided in a symmetric fashion. The examples presented herein are provided for clarity of understanding and are not meant to be limiting.

In accordance with one or more embodiments, a multi-layer electromagnetic device is provided. The device may include an antenna layer having an array of radiating elements arranged symmetrically with respect to at least one axis of symmetry; and a set of transmission lines through layers of the device, each transmission line in the set of transmission lines having a same electrical length. In various embodiments, the device may further include a resonant cavity formed by a plurality of micro-vias surrounding each radiating element. In one or more embodiments, the plurality of micro-vias may be configured through multiple layers of the device. In various embodiments, the device may further include a ground layer having a coupling slot formed therein. In one or more embodiments, the ground layer may include one or more core vias.

In various embodiments, the device may further include a routing layer having a transmission line and transmission line load formed therein.

In one or more embodiments, the antenna layer may include a first row of radiating elements comprising a first and second set of radiating elements, and wherein the first set of radiating elements is symmetric with the second set of radiating elements about a first axis of symmetry. In one or more embodiments, the antenna layer may include a second row of radiating elements symmetric to the first row with respect to a second axis of symmetry perpendicular to the first axis of symmetry.

In one or more embodiments, the device is an antenna in package (AIP) device. In various embodiments, the device may further include a transition output from the AiP device to an integrated circuit to control operation of the AiP. In various embodiments, the array of radiating elements is arranged symmetrically with respect to at least two axes of symmetry.

In accordance with various embodiments, a method for constructing an AiP device is provided. The method may include aligning a first set of radiating elements in a symmetric pattern; determining an electrical length of transmission lines for the radiating elements; and configuring paths for the transmission lines through a plurality of layers.

In various embodiments, the method may further include constructing a plurality of layers from an antenna layer to an integrated circuit connection layer. In various embodiments, the method may further include forming a resonant cavity in multiple layers of the device. In one or more embodiments, the resonant cavity is formed by a plurality of micro-vias. In one or more embodiments, the symmetric pattern may include at least two axes of symmetry, which may be perpendicular to one another.

In accordance with various embodiments, an antenna in package (AiP) is provided. The AiP may include a plurality of layers comprising a core layer, a ground layer, a set of parasitic patches positioned on an antenna layer, and a connection layer for connection to a controller, and a plurality of transmission lines through the plurality of layers, wherein each of the transmission lines has a same electrical length.

In various embodiments, the AiP may include one or more resonant cavities that are formed within the plurality of layers. In one or more embodiments, one or more resonant cavities may be formed by a plurality of micro-vias. In one or more embodiments, the plurality of layers may include an antenna layer having an array of radiating elements arranged symmetrically with respect to at least one axis of symmetry.

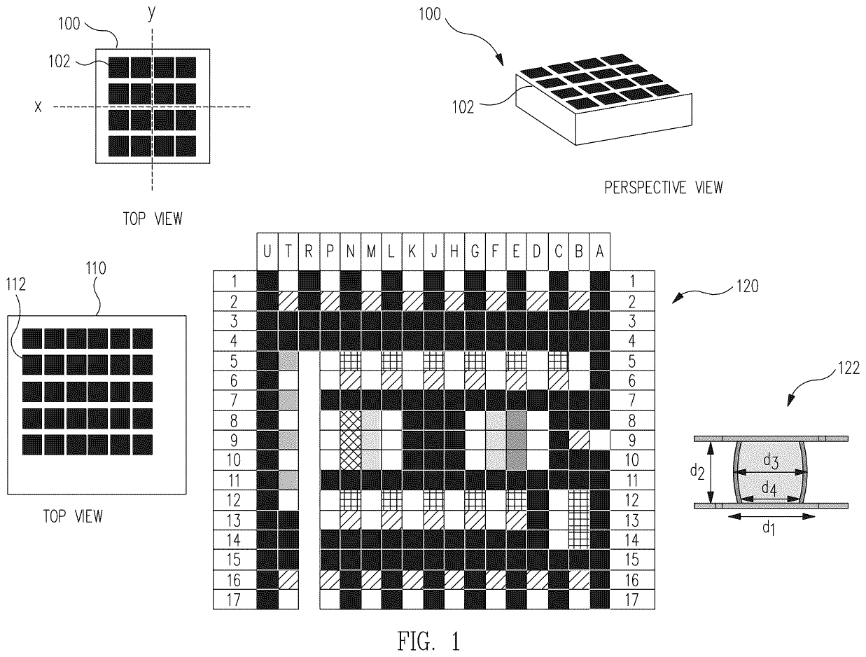

The disclosed apparatuses and methods of the present application are further illustrated and described with respect to FIGS. 1-9, as follows.

FIG. 1 illustrates an example configuration of an integrated circuity (IC) 100 having a plurality of elements 102 illustrated in a top view and a perspective view. The IC 100 is made up of multiple layers through which transmission lines or electrical conductors are configured. The present inventions are described as square structures where an equal number of radiating cells are positioned in each dimension. The configuration of cells is an array (4×4) and may be divided into subarrays. An example of a subarray configuration is illustrated as axis lines x and y, where the subarrays will be (2×2) cells subarrays.

In another example, an IC structure 110 is a (6×6) array, having 36 cells 112. This configuration of IC 110 is referred to as a mapping and may be extremely complex as illustrated in a mapping 120 of a layer within the IC 110. Each block of the layer is defined by different parameters, such as material, conductor, open and so forth. The conductive portions are coupled between layers by connectors, such as connector 122, which is shown with various internal dimensions d₁, d₂, d₃, and d₄ of the connector 122. The connectors may be conductive materials, open vias, vias with conductive perimeter and so forth depending on the design. These mappings become very complex as the functionality and frequency of operation change. In the present example, the IC 110 has 36 antenna elements 112 arranged as a (6×6) array, but any number of antenna elements 112 can be arranged as an array with suitable dimensions. As discussed herein, any suitable subarray configurations can be implemented with various array dimensions.

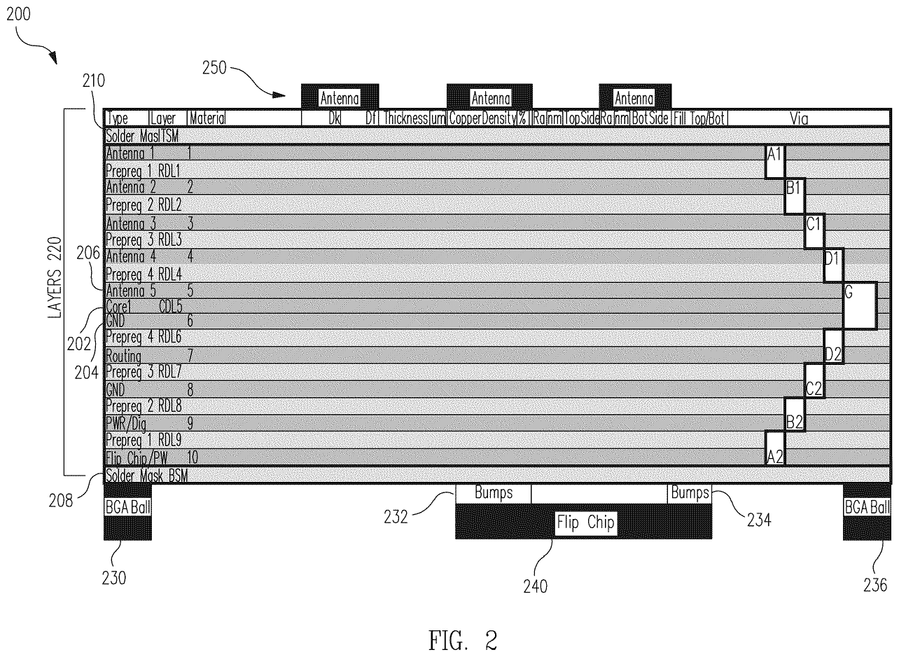

FIG. 2 illustrates a multi-layer device 200 incorporating configurations, mappings and formations, in accordance with various embodiments. The multi-layer device 200 may be a flip chip design having a ball grid array, also referred to as an “fcBGA” device, including layers with a flip chip 240 with bumps 230, 232, 234, 236, which are also referred to as chip pads 230, 232, 234, 236. The chip pads 230, 232, 234, 236 are coupled to various layers 220, which include flip chip layer, BGA pads metal layers, ground (metal) layers, dielectric (insulation) layers, and a solder mask or substrate layer, as illustrated in FIG. 2. The BGA structures positioned under the substrate (e.g., the layers of the fcBGA device/multi-layer device 200) include BGA balls.

Each layer of multi-layer device 200 is positioned and structured to facilitate circuitry and transmission paths supporting the flip chip 240 functionality and operation. These layers are connected through conductive paths, vias and other structures. Within a layer, there are conductive structures referred to as pads, that provide conductive connection between layers. Transmission lines are configured through these layers to connect antenna radiating element cells to source transmissions.

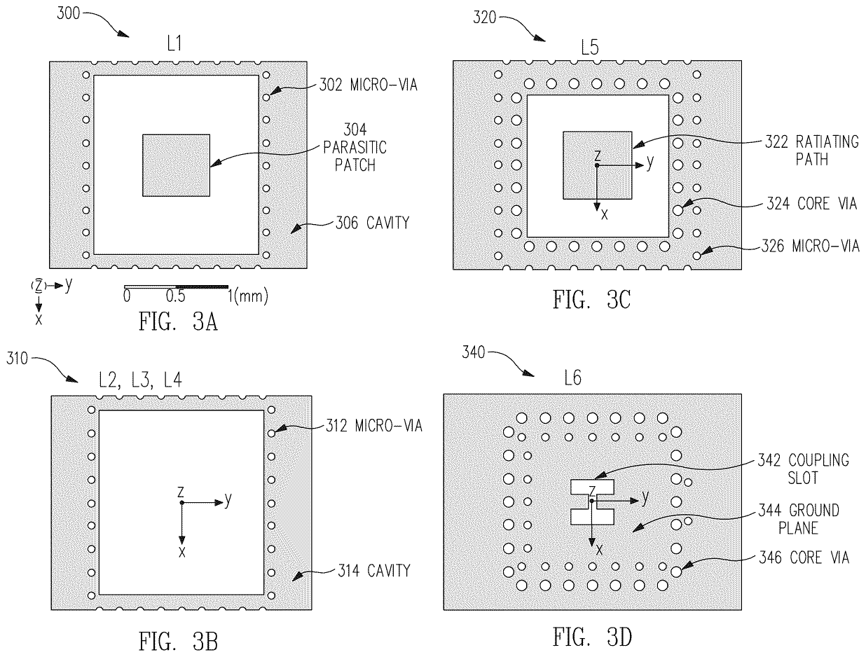

The multi-layer device 200 is a structure having transitions and connections through the various layers. FIGS. 3A-3D illustrate layers of an example multi-layer device, in accordance with various examples. FIG. 3A illustrates a portion 300 of the top layer L1 of the stack up with the chip pad, the parasitic patch 304, surrounded by an opening without metal. Micro-vias 302 are positioned around the perimeter of area 306 forming a resonant cavity for the slot-coupled patch antenna having parasitic patch 304. The via cage 302 acts to tune the matching center frequency for the antenna. The resonant cavity also helps suppress element-to-element coupling, such as via surface waves in the substrate, and improve antenna isolation.

As shown in FIG. 3B, layers L2, L3 and L4 have a structure 310 with continuation micro-vias 312 in a cavity 314. The layer L5, as shown in FIG. 3C, has a structure 320 with radiating patch 322 core vias 324 and micro-vias 326. The layer L6 shown in FIG. 3D has a structure 340 with a coupling slot 342 on a ground plane 344 with core vias 346 around the coupling slot 342.

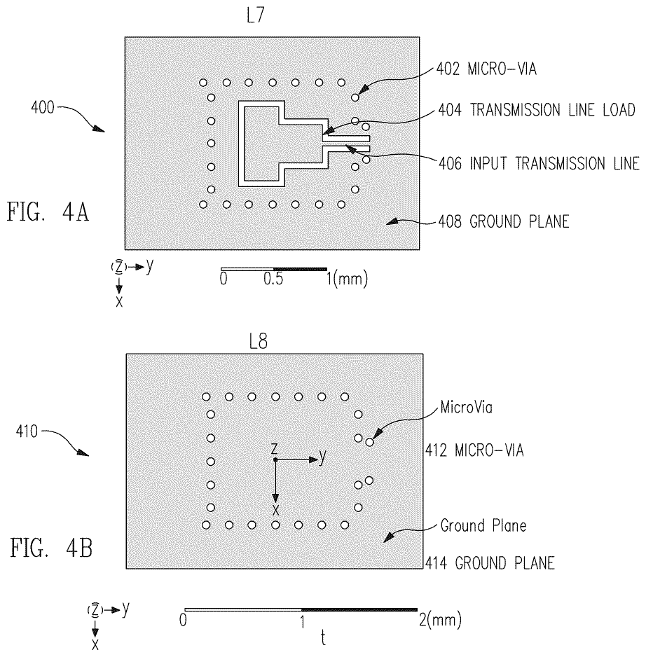

Continuing the structure 200 of FIG. 2, FIGS. 4A and 4B illustrate layers of an example multi-layer device, in accordance with various examples. As illustrated in FIGS. 4A and 4B, layers L7 and L8 have structures 400, 410, respectively. The structure 400 has a transmission line load structure 404 on a ground plan 408. The input transmission line structure 406 feeds the transmission line load structure 404. Micro-vias 402 surround the structures 404, 406. The layer L8 has a structure 410 with micro-vias 412 on a ground plane 414.

Designing the configuration of the multi-layer device 200 of FIG. 2 considers the parameters of the layers, such as, for example, but not limited to dielectric permittivity, loss tangent, thickness and roughness of each of the layers; these are considerations in the design, configuration, operation, manufacturability, application, cost and so forth of the device. The BGA balls 230, 232, 235, 236 connect the multi-layer device 200 to a main board or other application structure. The core layer 202, labeled core 1, is sandwiched between ground layer 204 and antenna layer 206. The solder mask layers 208 and 210 are positioned at opposite ends of the stack up 200. There is open spacing between the BGA balls 230, 232, 234, 236, and other examples may have any of a variety of configurations. In various embodiments, BGA balls may be of uniform size and shape. In various embodiments, BGA balls may be of nonuniform size and shape.

There are various transitions from the example of multi-layer device 200, with signal transmissions from antenna elements 250 to the BGA balls 230, 232, 234, 236 and further routing in the flip chip layer 240. The configuration of the stack up is designed to reduce unwanted reflections and increase transmission gain for a frequency range, which in this example is 78.5 GHz with 10 GHz of bandwidth.

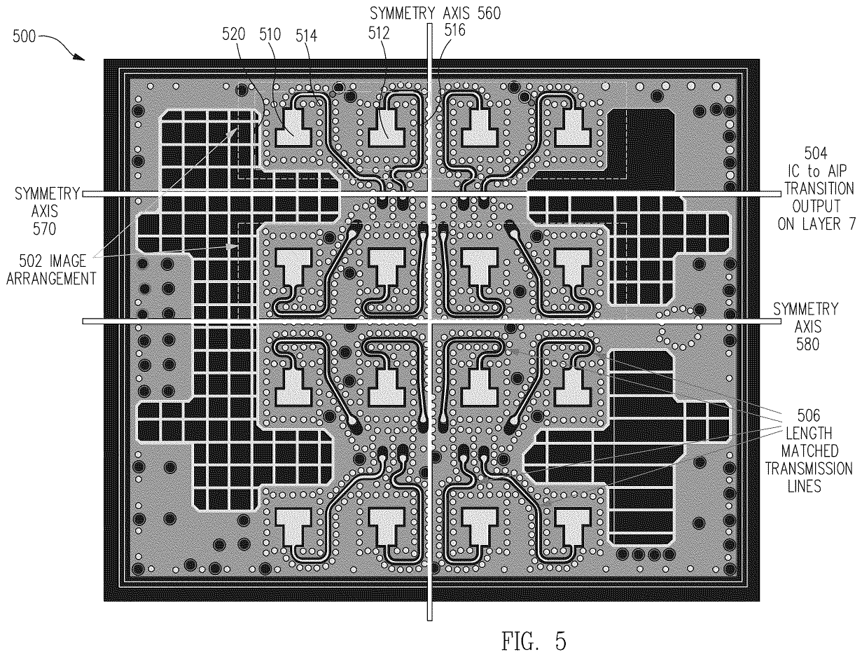

FIG. 5 illustrates a top view of an example multi-layer device, in accordance with various examples. Specifically, a top view of a structure 500 of the present invention is illustrated in FIG. 5. The image arrangements 502 are mirror images of each other around symmetry axis 570. Within each of image arrangements 502 are radiating elements 510, 512 with transmission lines 514, 516. During operation it is desired that the signals propagating through each of the transmission lines 514, 516, respectively, and to avoid introduction of different phase shifts due to differing transmission line path lengths and conditions. The transmission lines 514, 516 are sized and configured to have an equivalent electrical length to ensure the consistent electrical length and thereby maintain a consistent signal phase. By ensuring the same electrical length, the phase of the signal on each transmission path is maintained and avoids uneven phase shifts resulting in changes in operation. The image arrangement 502 has symmetry around symmetry axis 560. Image arrangement 502 is positioned symmetrically around symmetry axis 570. The structure 500 also has symmetry with respect to symmetry axis 580. Also identified in the structure 500 is a transition 504 from integrated circuit (IC) to antenna in package (AiP) on layer 7.

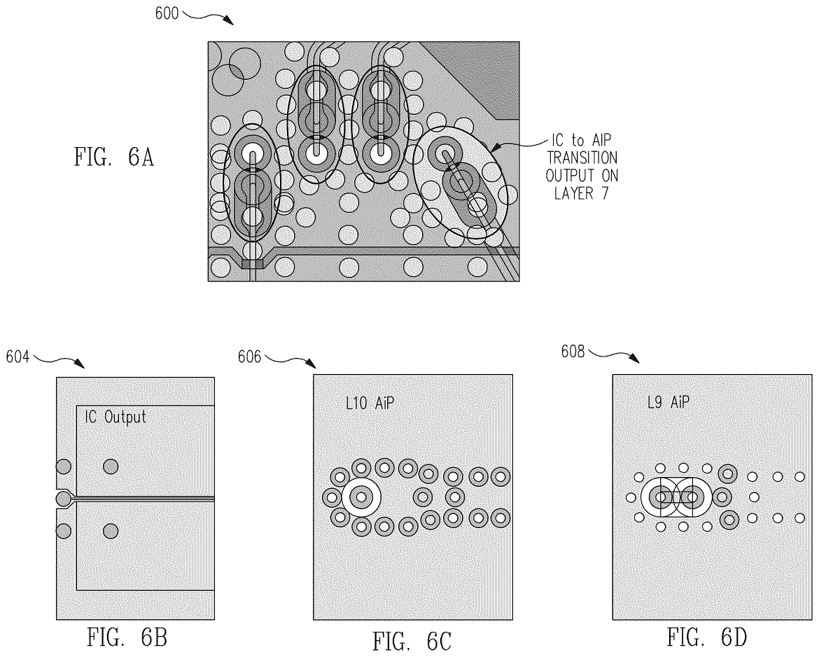

FIGS. 6A-6D illustrate a top view of multiple transitions in a layer of a multi-layer device, in accordance with various examples. Specifically, FIGS. 6A-6D illustrate IC-to-AiP RF frontend transition (from layer 10 to layer 7) structures 600, and an IC frontend output interface 604. Structure 606 of AiP layer 10 has a signal via transition surrounded by ground vias. Structure 608 of AiP layer 9 has a signal trace connecting two micro-vias (layer 10 to layer 9, and layer 9 to layer 8, respectively) surround by ground vias.

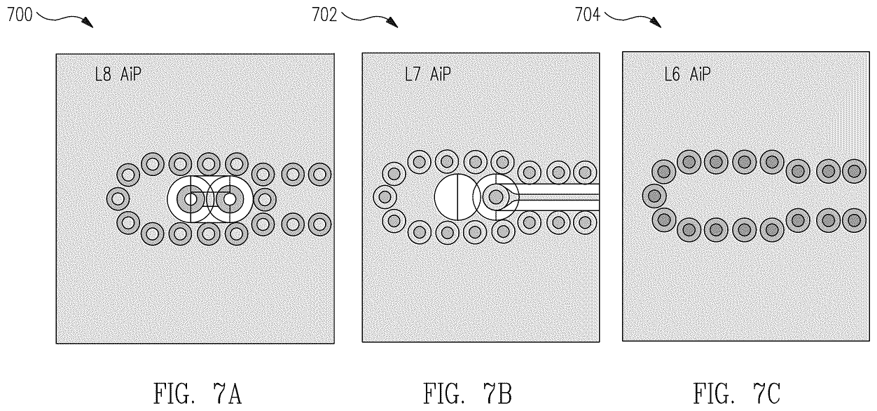

FIGS. 7A-7C illustrate a top view of multiple layers of configuration of transmission path transitions through a multi-layer device, in accordance with various examples. Specifically, FIGS. 7A-7C illustrate the remaining parts of IC-to-AiP RF frontend transition including structure 700 of AiP layer L8, structure 702 of layer L7, and structure 704 of layer L6, respectively. The layers illustrate the transmission line and vias mapping through structure 2 of FIG. 2.

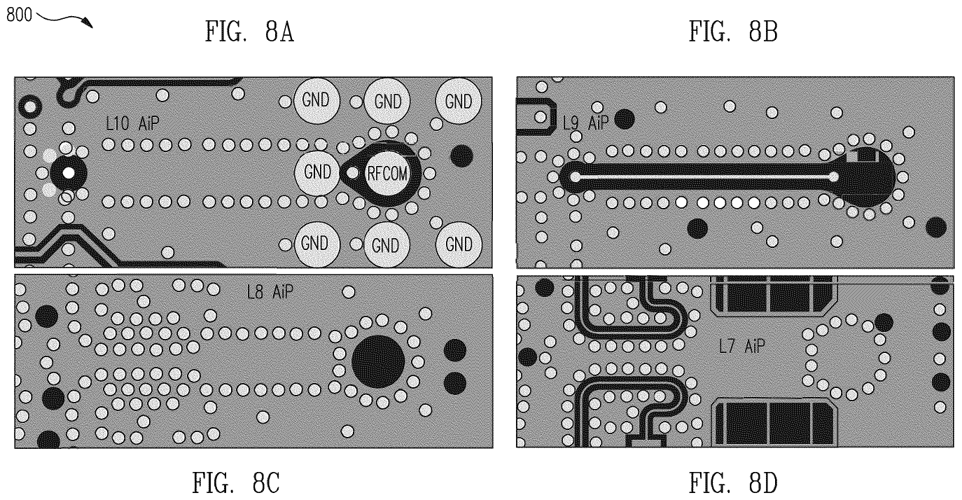

FIGS. 8A-8D illustrate a top view of multiple layers of configuration of transmission path transitions through a multi-layer device, in accordance with various examples. Specifically, FIGS. 8A, 8B, 8C, and 8D illustrate AiP RFCOM signal transition, e.g., layer 10, layer 9, layer 8 to layer 7, respectively, of structure 800. The RFCOM signal is the AiP RF input in transmit mode and the AiP RF output in receive mode. Structure 800 includes C4 pad and BGA pad transitions on layer 10, a stripline trace on layer 9, a ground plane with a circular void under BGA pad on layer 8, and another ground plane on layer 7. The AiP RFCOM transition design has a wideband matching from PCB RF signal trace to the IC. Dense shielding ground vias are placed around the signal transition in 800 to ensure sufficient isolation (i.e., over 50 dB) between RFCOM and RF frontend signals to/from the antenna.

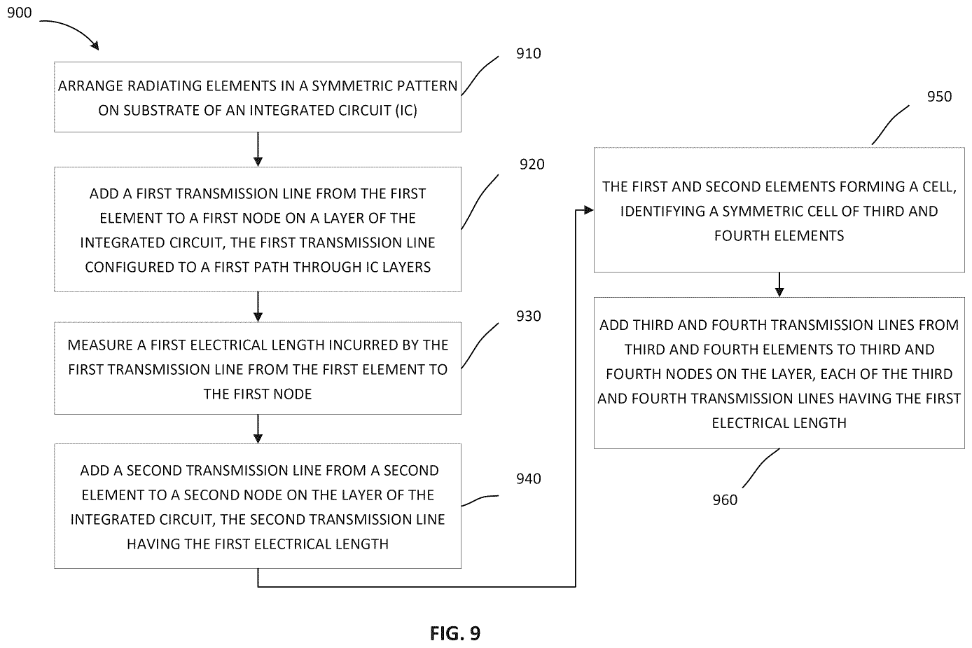

FIG. 9 is a flow chart for a process 900 of designing of a structure having array of radiating elements configured through a multi-layer structure with equal electrical length transmission lengths to maintain signal consistency through the device. As illustrated in FIG. 9, the process 900 includes at step 910, arranging radiating elements in a symmetric pattern on a substrate of an integrated circuit. Initial design of a transmission line from an antenna element to a node on a layer of the IC structure determines an electrical length of a first path through the structure. At step 920, the process 900 includes adding a first transmission line from a first element to a first node on a layer of the IC structure, where the first transmission line is configured as a first path through the IC structure. The process 900 further includes at step 930, measuring the electrical length of the first transmission line from the first element to the first node. Using this electrical length as a criterion, the process 900 further includes designing a next transmission line of an adjacent antenna element, at step 940, for example, by adding a second transmission line from a second element to a second node on the layer of the IC structure, where the second transmission line has a same length as that of the first transmission line. The radiating elements and transmission line design is duplicated and positioned symmetrically. At step 950, the process 900 includes forming a cell using the first and second elements, and then identifying a symmetric cell for third and fourth elements, similar to the cell comprising the first and second elements. From here additional transmission lines are designed with the electrical length. At step 960, the process 900 includes adding third and fourth transmission lines to third and fourth nodes, respectively, through the IC structure, wherein each of the third and fourth transmission lines have the same length as the first and second transmission lines.

It is appreciated that the previous description of the disclosed examples is provided to enable any person skilled in the art to make or use the present disclosure. Various modifications to these examples will be readily apparent to those skilled in the art, and the generic principles defined herein may be applied to other examples without departing from the spirit or scope of the disclosure. Thus, the present disclosure is not intended to be limited to the examples shown herein but is to be accorded the widest scope consistent with the principles and novel features disclosed herein.

As used herein, the phrase “at least one of” preceding a series of items, with the terms “and” or “or” to separate any of the items, modifies the list as a whole, rather than each member of the list (i.e., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

Furthermore, to the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate implementations can also be implemented in combination in a single implementation. Conversely, various features that are described in the context of a single implementation can also be implemented in multiple implementations separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. Moreover, the separation of various system components in the aspects described above should not be understood as requiring such separation in all aspects, and it should be understood that the described program components and systems can generally be integrated together in a single hardware product or packaged into multiple hardware products. Other variations are within the scope of the following claim.

### EMBODIMENTS

Various embodiments follow, but are not meant to be all embodiments of the present disclosure.

Embodiment 1: A multi-layer electromagnetic device, comprising: an antenna layer having an array of radiating elements arranged symmetrically with respect to at least one axis of symmetry; and a set of transmission lines through layers of the device, each transmission line in the set of transmission lines having a same electrical length.

Embodiment 2: The device of embodiment 1, further comprising: a resonant cavity formed by a plurality of micro-vias surrounding each radiating element.

Embodiment 3: The device of embodiment 2, wherein the plurality of micro-vias is configured through multiple layers of the device.

Embodiment 4: The device of embodiment 3, further comprising a ground layer having a coupling slot formed therein.

Embodiment 5: The device of any one of embodiments 1-4, wherein core vias are formed in the ground layer.

Embodiment 6: The device of any one of embodiments 1-5, further comprising a routing layer having a transmission line and transmission line load formed therein.

Embodiment 7: The device of any one of embodiments 1-6, wherein the antenna layer comprises a first row of radiating elements comprising a first and second set of radiating elements, and wherein the first set of radiating elements is symmetric with the second set of radiating elements about a first axis of symmetry.

Embodiment 8: The device of embodiment 7, wherein the antenna layer comprises a second row of radiating elements symmetric to the first row with respect to a second axis of symmetry perpendicular to the first axis of symmetry.

Embodiment 9: The device of any one of embodiments 1-8, wherein the device is an antenna in package (AIP) device.

Embodiment 10: The device of embodiment 9, further comprising a transition output from the AiP device to an integrated circuit to control operation of the AiP.

Embodiment 11: The device of any one of embodiments 1-10, wherein the array of radiating elements is arranged symmetrically with respect to at least two axes of symmetry.

Embodiment 12: A method for constructing an AiP device, comprising: aligning a first set of radiating elements in a symmetric pattern; determining an electrical length of transmission lines for the radiating elements; and configuring paths for the transmission lines through a plurality of layers.

Embodiment 13: The method of embodiment 12, further comprising: constructing a plurality of layers from an antenna layer to an integrated circuit connection layer.

Embodiment 14: The method of embodiment 13, further comprising: forming a resonant cavity in multiple layers of the device.

Embodiment 15: The method of embodiment 14, wherein the resonant cavity is formed by a plurality of micro-vias.

Embodiment 16: The method of any one of embodiments 12-15, wherein the symmetric pattern comprises at least two axes of symmetry.

Embodiment 17: An antenna in package (AiP), comprising: a plurality of layers comprising: a core layer; a ground layer; a set of parasitic patches positioned on an antenna layer; a connection layer for connection to a controller; and a plurality of transmission lines through the plurality of layers, wherein each of the transmission lines has a same electrical length.

Embodiment 18: The AiP of embodiment 17, wherein a resonant cavity is formed within the plurality of layers.

Embodiment 19: The AiP of embodiment 18, wherein the resonant cavity is formed by a plurality of micro-vias.

Embodiment 20: The AiP of any one of embodiments 17-19, wherein the plurality of layers comprises an antenna layer having an array of radiating elements arranged symmetrically with respect to at least one axis of symmetry.

What is claimed is:

1. A multi-layer electromagnetic device, comprising:
an antenna layer having an array of radiating elements arranged symmetrically with respect to at least one axis of symmetry; and
a set of transmission lines through layers of the device, each transmission line in the set of transmission lines having a same electrical length.

2. The device of claim 1, further comprising:
a resonant cavity formed by a plurality of micro-vias surrounding each radiating element.

3. The device of claim 2, wherein the plurality of micro-vias is configured through multiple layers of the device.

4. The device of claim 3, further comprising a ground layer having a coupling slot formed therein.

5. The device of claim 4, wherein core vias are formed in the ground layer.

6. The device of claim 1, further comprising a routing layer having a transmission line and transmission line load formed therein.

7. The device of claim 1, wherein the antenna layer comprises a first row of radiating elements comprising a first and second set of radiating elements, and wherein the first set of radiating elements is symmetric with the second set of radiating elements about a first axis of symmetry.

8. The device of claim 7, wherein the antenna layer comprises a second row of radiating elements symmetric to the first row with respect to a second axis of symmetry perpendicular to the first axis of symmetry.

9. The device of claim 1, wherein the device is an antenna in package (AIP) device.

10. The device of claim 9, further comprising a transition output from the AiP device to an integrated circuit to control operation of the AiP.

11. The device of claim 1, wherein the array of radiating elements is arranged symmetrically with respect to at least two axes of symmetry.

12. A method for constructing an AiP device, comprising:
aligning a first set of radiating elements in a symmetric pattern;
determining an electrical length of transmission lines for the radiating elements; and
configuring paths for the transmission lines through a plurality of layers.

13. The method of claim 12, further comprising:
constructing a plurality of layers from an antenna layer to an integrated circuit connection layer.

14. The method of claim 13, further comprising:
forming a resonant cavity in multiple layers of the device.

15. The method of claim 14, wherein the resonant cavity is formed by a plurality of micro-vias.

16. The method of claim 12, wherein the symmetric pattern comprises at least two axes of symmetry.

17. An antenna in package (AiP), comprising:
a plurality of layers comprising:
a core layer;
a ground layer;
a set of parasitic patches positioned on an antenna layer;
a connection layer for connection to a controller; and
a plurality of transmission lines through the plurality of layers, wherein each of the transmission lines has a same electrical length.

18. The AiP of claim 17, wherein a resonant cavity is formed within the plurality of layers.

19. The AiP of claim 18, wherein the resonant cavity is formed by a plurality of micro-vias.

20. The AiP of claim 17, wherein the plurality of layers comprises an antenna layer having an array of radiating elements arranged symmetrically with respect to at least one axis of symmetry.
